(19) United States
(12) Patent Application Publication
(10) Pub. No.: US 2013/0292763 A1
(43) Pub. Date: Nov. 7, 2013

(54) Semiconductor Devices Having Reduced On Resistance

(71) Applicant: SAMSUNG ELECTRONICS CO., LTD., Suwon-si (KR)

(72) Inventors: Hoon Chang, Suwon-si (KR); Jae-June Jang, Hwaseong-si (KR)

(73) Assignee: Samsung Electronics Co., Ltd., Suwon-si (KR)

(21) Appl. No.: 13/865,506

(22) Filed: Apr. 18, 2013

(30) Foreign Application Priority Data
May 2, 2012 (KR) 10-2012-0046349

(51) Int. Cl. H01L 29/78

(52) U.S. Cl. CPC H01L 29/7816
USPC 257/335

(57) ABSTRACT

Semiconductor devices are provided including a substrate having a first conductivity type; a source region having a second conductivity type, different from the first conductivity type; a drain region, separate from the source region and having the second conductivity type; a body region having the first conductivity type and on the substrate surrounding side and bottom surfaces of the source region; a drift region having the second conductivity type, the drift region being on the substrate surrounding side and bottom surfaces of the drain region; a first gate on the body region; and an electrically floating second gate, separate from the first gate, on the drift region.

### CLAIM OF PRIORITY

This application claims priority from Korean Patent Application No. 10-2012-0046349, filed May 2, 2012 in the Korean Intellectual Property Office, the disclosure of which is hereby incorporated herein by reference in its entirety.

### FIELD

The present inventive concept relates generally to a semiconductor device and, more particularly, to semiconductor devices including oxide films and nitride layers and related methods of fabricating the same.

### BACKGROUND

A power metal-oxide field-effect transistor (MOSFET) has a higher power gain and a simpler gate driving circuit than a bipolar transistor. Furthermore, when the power MOSFET is turned off, there is no time delay caused by accumulation or recombination of minority carriers. Therefore, the power MOSFET is widely used as a control, logic and power switch.

An example of the power MOSFET is a double diffused MOSFET (DMOS) using double diffusion technology, such as a lateral DMOS (LDMOS).

An oxide film may be formed on a drift region of an LDMOS by local oxidation of silicon (LOCOS) process or a shallow trench isolation (STI) process. The oxide film can reduce the likelihood that an electric field will be concentrated on the drift region of the LDMOS and, thus, possibly reducing a breakdown voltage. However, since a current path is formed alongside and on bottom surfaces of the oxide film, the length of the current path is increased, thereby increasing on-resistance (Ron).

An LDMOS having a voltage of 20 V or less may utilize a silicide blocking layer instead of an oxide film formed by the LOCOS process or the STI process. The silicide blocking layer can reduce the likelihood that the on-resistance will increase. However, imperfect quality of a nitride layer formed on the silicide blocking layer may cause charge trapping during the operation of the LDMOS. The charge trapping can deteriorate the reliability of the LDMOS.

### SUMMARY

Aspects of the present inventive concept provide semiconductor devices having an on-resistance that can be reduced since a length of a current path is reduced by, for example, not using an oxide film formed by a local oxide of silicon (LOCOS) process or a shallow trench isolation (STI) process and in which the likelihood of charge trapping can be reduced by not using a nitride layer.

Some embodiments of the present inventive concept provide a semiconductor device including a substrate having a first conductivity type; a source region and a drain region having a second conductivity type, different from the first conductivity type and formed on the substrate to be separated from each other; a body region having the first conductivity type on the substrate such that the body region surrounds side and bottom surfaces of the source region; a drift region having the second conductivity type on the substrate such that the drift region surrounds side and bottom surfaces of the drain region; a first gate on the body region, and a second electrically floating gate, separate from the first gate, on the drift region.

Further embodiments of the present inventive concept provide semiconductor devices including a substrate having a first conductivity type; a drift region having a second conductivity type, different from the first conductivity type, and formed on the substrate; an electrically floating gate on the drift region; a body region having the first conductivity type on the substrate adjacent to the drift region; a source region having the second conductivity type in the body region; a gate on a first side of the floating gate that extends from the drift region to the body region and to which a predetermined voltage is applied; and a drain region having the second conductivity type on a second side of the floating gate in the drift region.

Aspects of the present inventive concept are not restricted to embodiments discussed herein. The above and other aspects of the present inventive concept will become more apparent to one of ordinary skill in the art to which the present inventive concept pertains by referencing the detailed description of the present inventive concept given below.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a cross-section of a semiconductor device 1 according to some embodiments of the present inventive concept.

FIG. 2 is a cross-section of a semiconductor device 2 according to some embodiments of the present inventive concept.

FIG. 3 is a cross-section of a semiconductor device 3 according to some embodiments of the present inventive concept.

FIG. 4 is a cross-section of a semiconductor device 4 according to a fourth embodiment of the present inventive concept.

FIGS. 5 through 8 are cross-sections illustrating processing steps in the fabrication of semiconductor devices according to some embodiments of the present inventive concept illustrated in FIG. 1.

FIGS. 9 through 11 are cross-sections illustrating processing steps in the fabrication of semiconductor devices according to some embodiments of the present inventive concept illustrated in FIG. 2.

FIG. 12 is a block diagram of a semiconductor system according to some embodiments of the present inventive concept.

FIG. 13 is a block diagram of a semiconductor system according to some embodiments of the present inventive concept.

FIG. 14 is a conceptual diagram of a semiconductor system according to some embodiment of the present inventive concept.

FIG. 15 is a conceptual diagram of a semiconductor system according to some embodiments of the present inventive concept.

### DETAILED DESCRIPTION OF THE EMBODIMENTS

The present invention will now be discussed more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements discussed as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

The present invention will be discussed with reference to perspective views, cross-sections, and/or plan views, in which preferred embodiments of the invention are shown. Thus, the profile of an exemplary view may be modified according to manufacturing techniques and/or allowances. That is, the embodiments of the invention are not intended to limit the scope of the present invention but cover all changes and modifications that can be caused due to a change in manufacturing process. Thus, regions shown in the drawings are illustrated in schematic form and the shapes of the regions are presented simply by way of illustration and not as a limitation.

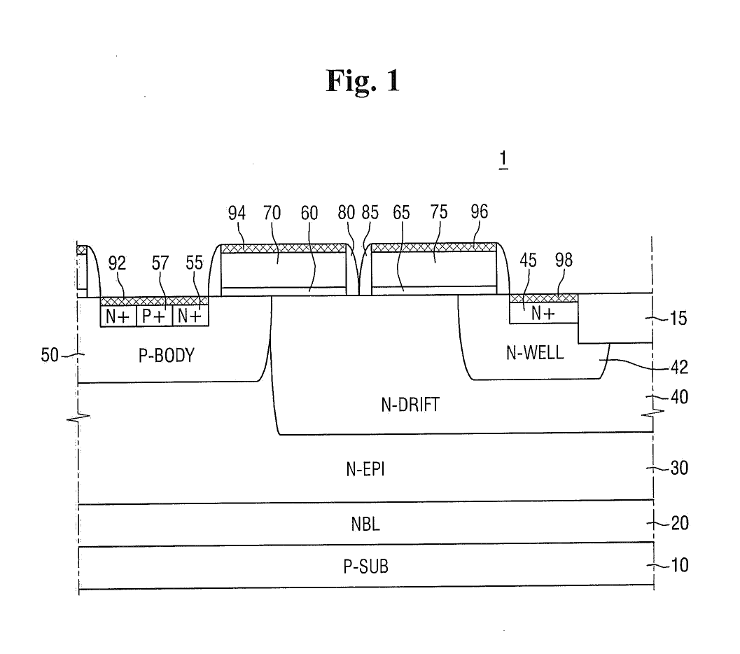

Semiconductor device according to some embodiments of the present inventive concept will now be discussed with reference to FIG. 1. The semiconductor device according to the first embodiment of the present inventive concept may be, but is not limited to, a lateral double diffused MOSFET (LDMOS). For ease of description; embodiments where the semiconductor device of the present inventive concept is an LDMOS of a second conductivity type, for example, an N type, will be discussed. However, the present inventive concept is not limited to this configuration. As is understood to those of ordinary skill in the art that the technical spirit of the semiconductor device of the present inventive concept can also be applied to embodiments where the semiconductor device of the present inventive concept is an LDMOS of a first conductivity type, for example, a P type. This is possible by changing example conductivity types used in the following description.

Referring now to FIG. 1, a cross-section of a semiconductor device 1 according to some embodiments of the present inventive concept will be discussed. As illustrated in FIG. 1, the device includes a substrate 10 that may be a semiconductor substrate doped with impurities of the first conductivity type, for example, a P type. The substrate 10 may be, but is not limited to, a silicon substrate, a gallium arsenide substrate, a silicon germanium substrate, a ceramic substrate, a quartz substrate or a glass substrate for displays or may be a semiconductor on insulator (SOI) substrate.

A buried layer 20 provided on the substrate 10 may be doped with impurities of the second conductivity type, for example, an N type, different from the first conductivity type. In some embodiments of the present inventive concept, the buried layer 20 of the second conductivity type, for example, an N type, may be formed at a boundary between the substrate 10 and an epitaxial layer 30.

Specifically, to form a portion of the buried layer 20 in the substrate 10 and the other portion of the buried layer 20 in the epitaxial layer 30, the buried layer 20 may be formed in the substrate 10, and the epitaxial layer 30 may be formed on the substrate 10. Then, a heat treatment process may be performed. The heat treatment process may cause the buried layer 20 to diffuse to the substrate 10 and the epitaxial layer 30. As a result, a portion of the buried layer 20 may be formed in the substrate 10, and the other portion of the buried layer 20 may be formed in the epitaxial layer 30.

The epitaxial layer 30 may be doped with impurities of the second conductivity type, for example, an N type. In these embodiments, a doping concentration of the epitaxial layer 30 may be lower than that of the buried layer 20. The epitaxial layer 30 may be formed on the buried layer 20, and a drift region 40, a body region 50, and an element isolation region 15 may be formed within the epitaxial layer 30 as illustrated in FIG. 1.

The drift region 40 may be doped with impurities of the second conductivity type, for example, an N type. In these embodiments, a doping concentration of the drift region 40 may be higher than that of the epitaxial layer 30. The drift region 40 may be formed within the epitaxial layer 30 to, for example, a first depth. The drift region 40 may be formed adjacent to the body region 50. In FIG. 1, an upper region of the body region 50 contacts an upper region of the drift region 40. However, the present inventive concept is not limited thereto. For example, the body region 50 and the drift region 40 may be separated from each other. Alternatively, the drift region 40 may surround the body region 50.

A well region 42 and a drain region 45 may be formed within the drift region 40. The well region 42 may be doped with impurities of the second conductivity type, for example, an N type. In these embodiments, a doping concentration of the well region 42 may be higher than that of the drift region 40. Furthermore, the well region 42 may be formed to a second depth smaller than the first depth. In some embodiments, the well region 42 is shallower than the drift region 40 but may be formed to a depth substantially equal to that of the body region 50.

The drain region 45 may be doped with impurities of the second conductivity type, for example, an N type. In these embodiments, a doping concentration of the drain region 45 may be higher than that of the well region 42. Side and bottom surfaces of the drain region 45 may be surrounded by the well region 42 and the drift region 40.

A drain silicide pattern 98 may be formed on the drain region 45. A contact plug for applying, for example, a high voltage, for example, 20 V or less, may be formed on the drain silicide pattern 98.

The element isolation region 15 may be formed adjacent to, for example, the drain region 45. Specifically, the element isolation region 15 may be, but is not limited to, an oxide film formed by a local oxidation of silicon (LOCOS) process or a shallow trench isolation (STI) process. The element isolation region 15 of the semiconductor device 1 according to some embodiments of the present inventive concept is formed to define an active region but is not formed to reduce the likelihood of a reduction in a breakdown voltage of the drift region 40. Therefore, the element isolation region 15 is not located in the drift region 40 between the drain region 45 and a source region 55.

The body region 50 may be doped with impurities of the first conductivity type, for example, the P type. The body region 50 may be formed within the epitaxial layer 30. The body region 50 may be formed to, for example, the second depth smaller than the first depth. The source region 55 and an ohmic contact region 57 may be formed within the body region 50. Specifically, the source region 55 and the ohmic contact region 57 may be formed adjacent to a top surface of the body region 50. When the semiconductor device 1 according to some embodiments of the present inventive concept is an LDMOS of the second conductivity type, for example, an N type, the body region 50 and the ohmic contact region 57 may be of the first conductivity type, for example, the P type, and the source region 55 may be of the second conductivity type, for example, an N type.

The source region 55 may be doped with impurities of the second conductivity type, for example, an N type. Furthermore, the body region 50 may surround, for example, side and bottom surfaces of the source region 55.

The ohmic contact region 57 may be doped with impurities of the first conductivity type, for example, the P-type. In these embodiments, a doping concentration of the ohmic contact region 57 may be higher than that of the body region 50. A bias voltage may be applied to the body region 50 through the ohmic contact region 57.

As illustrated in FIG. 1, the source region 55 and the ohmic contact region 57 neighbor each other. However, the present inventive concept is not limited thereto. The source region 55 and the ohmic contact region 57 can be separated from each other without departing from the scope of the present inventive concept.

A body silicide pattern 92 may be formed on the source region 55 and the ohmic contact region 57. A contact plug for applying, for example, a bias voltage may be formed on the body silicide pattern 92.

A first gate 70 may be formed on the body region 50. In particular, the first gate 70 may extend from on the drift region 40 to on the body region 50. That is, a region of the first gate 70 may be formed on the drift region 40, and the other region of the first gate 70 may be formed on the body region 50. The first gate 70 may be formed between the drain region 45 and the source region 55 and may be formed adjacent to the source region 55.

The first gate 70 may be, but not limited to, any one of a polysilicon gate and a metal gate. To operate the semiconductor device 1, a predetermined voltage may be applied to the first gate 70.

A first gate insulating film pattern 60 may be formed under the first gate 70. The first gate insulating film pattern 60 may be, but is not limited to, a high-K film pattern. A first gate silicide pattern 94 may be formed on the first gate 70. A first spacer 80 may be formed on both sides of the first gate 70. The first spacer 80 may be, but is not limited to, an oxide film spacer.

A second gate 75 may be separated from the first gate 70 and may be formed on the drift region 40. The second gate 75 may be formed between the drain region 45 and the source region 55 and may be formed adjacent to the drain region 45.

The second gate 75 may be made of the same material as the first gate 70. However, the present inventive concept is not limited thereto. The second gate 75 may be, but is not limited to, any one of a polysilicon gate and a metal gate.

A second gate insulating film pattern 65 may be formed under the second gate 75. The second gate insulating film pattern 65 may be, but is not limited to, a high-K film pattern. A second gate silicide pattern 96 may be formed on the second gate 75. A second spacer 85 may be formed on both sides of the second gate 75. The second spacer 85 may be, but is not limited to, an oxide film spacer.

In the semiconductor device 1 according some embodiments of the present inventive concept, a gap between the first gate 70 and the second gate 75 may be, for example, equal to or less than twice a width of a spacer. Therefore, the first spacer 80 and the second spacer 85 located between the first gate 70 and the second gate 75 may contact each other. In these embodiments, since the gap between the first gate 70 and the second gate 75 is filled with the first and second spacers 80 and 85, the drift region 40 located between the first spacer 80 and the second spacer 85 is not exposed during a fabrication process of the semiconductor device 1. Therefore, no silicide pattern may be formed on a region of the drift region 40 located between the first gate 70 and the second gate 75.

Unlike the first gate 70, the second gate 75 may be a floating gate which is electrically floating. The first gate 70 may be located on a first side of the second gate 75, and the drain region 45 may be located on a second side of the second gate 75. In these embodiments, the first gate 70 and the drain region 45 may be separated from each other by the second gate 75. Therefore, even if a high voltage, for example, 20 V or less, is applied to the drain region 45, a likelihood of a reduction in the breakdown voltage by a high electric field formed between the drain region 45 and an edge of the first gate 70 can be reduced.

Furthermore, since the second gate 75 is formed on the drift region 40 between the first gate 70 and the drain region 45, no silicide pattern may be formed on the drift region 40 between the first gate 70 and the drain region 45 while the second gate silicide pattern 96 is formed on the second gate 75. In these embodiments, since no silicide pattern is formed between the second gate 75 and the drift region 40, a high voltage applied to the drain region 45 cannot be delivered to the first gate 70. It can prevent being formed a high electric field at the edge of the first gate 70.

Furthermore, as discussed above, in the semiconductor device 1 according to some embodiments of the present inventive concept, an oxide film formed by a LOCOS process or an STI process is not located in the drift region 40 between the drain region 45 and the source region 55. Instead, the electrically floating second gate 75 may be formed on the drift region 40 between the drain region 45 and the source region 55. Therefore, a current path is not blocked by the oxide film. In these embodiments, the current path does not have to detour alongside and bottom surfaces of the oxide film. Instead, a straight current path may be formed between the drain region 45 and the source region 55. Therefore, a length of the current path in the semiconductor device 1 according to the some embodiments of the present inventive concept can be reduced, thus reducing on-resistance (Ron).

Moreover, as discussed above, in the semiconductor device 1 according to some embodiments of the present inventive concept, a suicide block layer is not used to separate the first gate 70 from the drain region 45. Instead, the electrically floating second gate 75 may be used. In some embodiments, since the semiconductor device 1 according to some embodiments of the present inventive concept does not use a silicide blocking layer, it may not use a nitride layer needed when using the silicide blocking layer. Therefore, the likelihood of charge trapping can be reduced, which, in turn, increases the reliability of the semiconductor device 1.

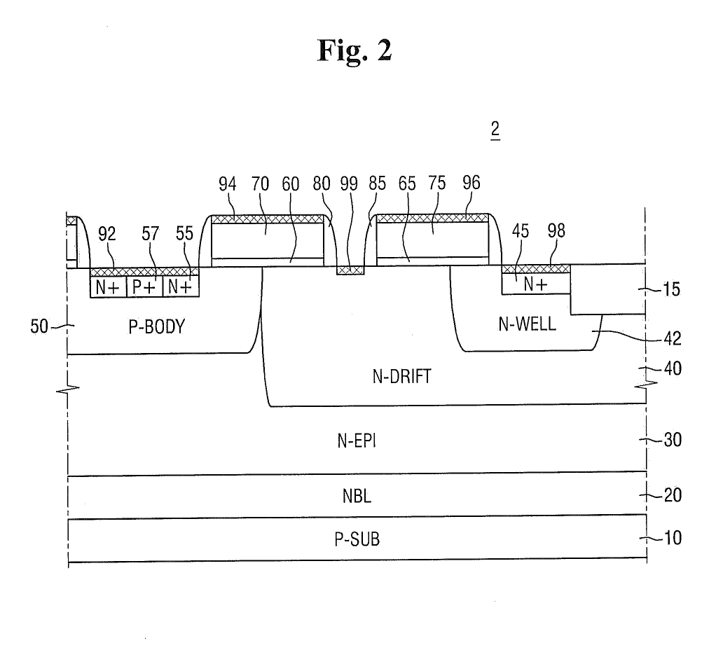

A semiconductor device according to some embodiments of the present inventive concept will now be discussed with reference to FIG. 2. For simplicity, the following description will focus on differences from the semiconductor device 1 discussed above.

Referring now to FIG. 2, a cross-section of a semiconductor device 2 according to some embodiments of the present inventive concept will be discussed. As illustrated in FIG. 2, in the semiconductor device 2 according to the second embodiment of the present inventive concept, a gap between a first gate 70 and a second gate 75 may be, for example, greater than twice a width of a spacer. Therefore, a first spacer 80 and a second spacer 85 located between the first gate 70 and the second spacer 75 may be separated from each other. In some embodiments, the first spacer 80 and the second spacer 85 located between the first gate 70 and the second gate 75 may not contact each other.

Since the gap between the first gate 70 and the second gate 75 is not completely filled with the first and second spacers 80 and 85, a portion of a drift region 40 located between the first spacer 80 and the second spacer 85 may be exposed during a fabricating process of the semiconductor device 2. Therefore, a drift silicide pattern 99 may be formed on a region of the drift region 40 located between the first gate 70 and the second gate 75.

Even if the drift silicide pattern 99 is formed, the electrically floating second gate 75 of the semiconductor device 2 according some embodiments of the present inventive concept can reduce the likelihood of a reduction in the breakdown voltage, reduce on-resistance (Ron), and increase the reliability of the semiconductor device 2.

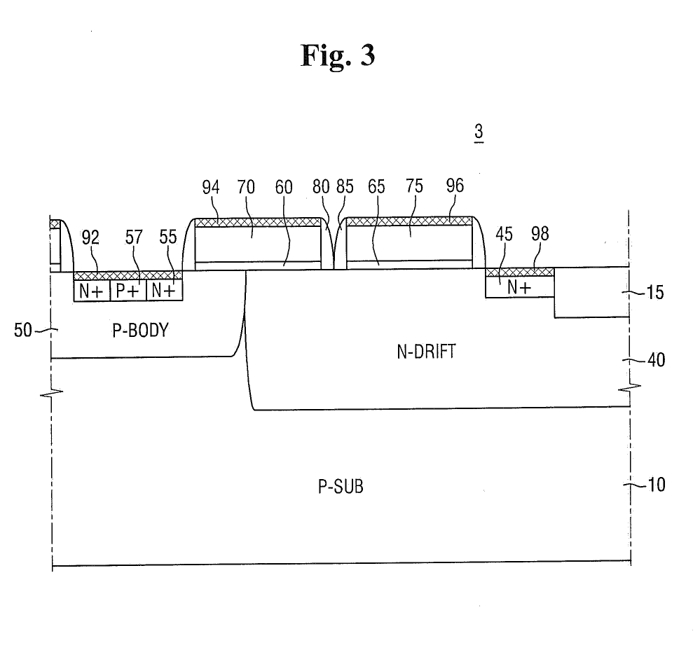

A semiconductor device according to some embodiments of the present inventive concept will now be discussed with reference to FIG. 3. For simplicity, the following description will focus on differences from the semiconductor device 1 discussed above.

Referring now to FIG. 3, a cross-section of a semiconductor device 3 according to some embodiments the present inventive concept will be discussed. As illustrated in FIG. 3, the semiconductor device 3 may not include a buried layer, an epitaxial layer, and a well region. A body region 50 and a drift region 40 may be formed on a substrate 40. Specifically, the drift region 40 may surround side and bottom surfaces of a drain region 45.

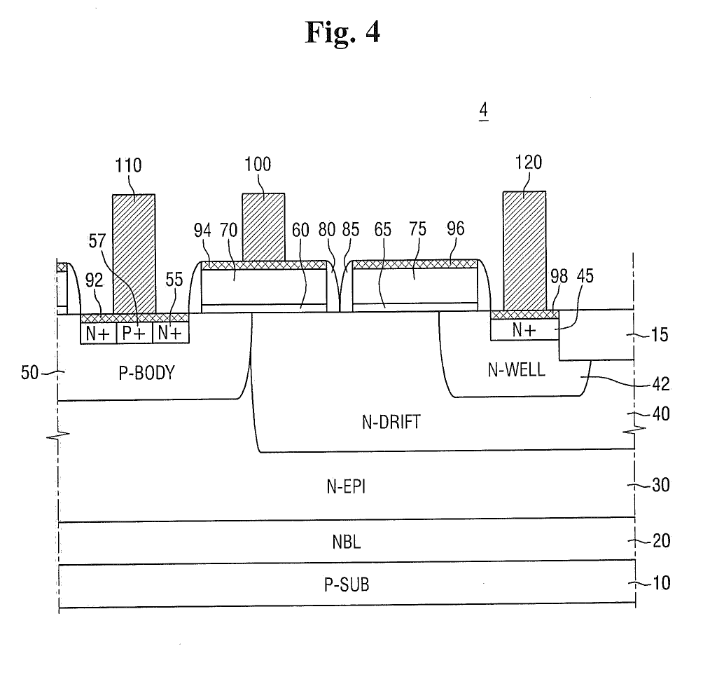

A semiconductor device according to some embodiments of the present inventive concept will now be discussed with reference to FIG. 4. For simplicity, the following description will focus on differences from the semiconductor device 1 discussed above.

Referring now to FIG. 4, a cross-section of a semiconductor device 4 according to some embodiments of the present inventive concept will be discussed. As illustrated in FIG. 4, the semiconductor device 4 may include first through third contact plugs 100 through 120. The first contact plug 100 may be formed on a first gate 70 and electrically connected to the first gate 70. In particular, the first contact plug 100 may be formed on, for example, a first gate silicide pattern 94. To operate the semiconductor device 4, a predetermined voltage may be applied to the first gate 70 through the first contact plug 100. However, since the second gate 75 is an electrically floating gate, a contact plug electrically connected to the second gate 75 may not be formed on the second gate 75.

The second contact plug 110 may be formed on a body region 50. Specifically, the second contact plug 110 may be formed on, for example, a body silicide pattern 92 on a source region 55 and an ohmic contact region 57. Furthermore, a bias voltage may be applied through the second contact plug 110.

The third contact plug 120 may be formed on a drain region 45. Specifically, the third contact plug 120 may be formed on, for example, a drain silicide pattern 98 on the drain region 45. A high voltage, for example, 20 V or less, may be applied to the drain region 45 through the third contact plug 120.

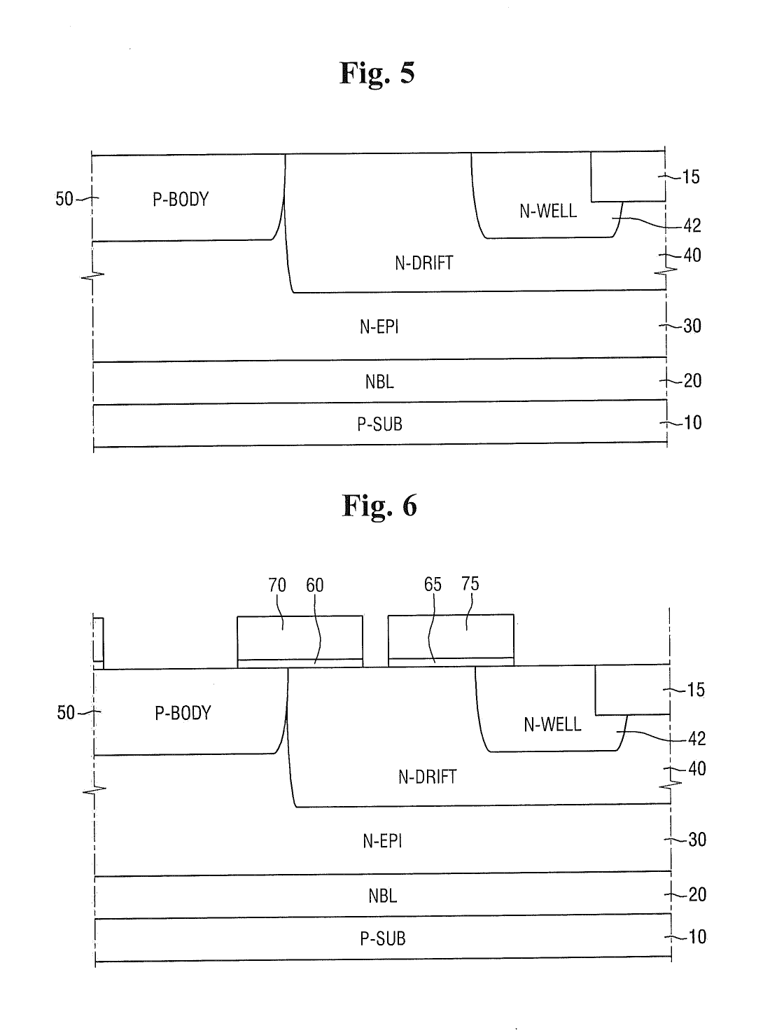

Processing steps in the fabrication of semiconductor devices according to some embodiments of the present inventive concept will now be discussed with reference to FIGS. 1 and 5 through 8. FIGS. 5 through 8 are cross-sections illustrating processing steps in the fabrication of semiconductor devices illustrated in FIG. 1.

Referring first to FIG. 5, a buried layer 20 of a second conductivity type, for example, an N type, may be formed in a substrate 10 of a first conductivity, for example, the P type. Then, an epitaxial layer 30 of the second conductivity type, for example, an N type, may be formed on the buried layer 20 using, for example, a selective epitaxial growth (SEG) method or a solid phase epitaxial (SPE) method.

Within the epitaxial layer 30, a drift region 40 of the second conductivity type, for example, an N type, may be formed to a first depth. Within the epitaxial layer 30, a body region 50 of the first conductivity type, for example, the P type, may be formed to a second depth smaller than the first depth. Also, a well region of the second conductivity type, for example, an N type, may be formed to the second depth within the drift region 40.

To define an active region, an element isolation region 15 may be formed on the substrate 10 by a LOCOS process or an STI process.

Referring to FIG. 6, a gate insulating film and a gate film may be formed sequentially on the intermediate structure of FIG. 5. Then, the gate insulating film and the gate film may be patterned to form first and second gate insulating film patterns 60 and 65 and first and second gates 70 and 75.

The first gate 70 and the second gate 75 may be separated from each other. A gap between the first gate 70 and the second gate 75 may be, for example, equal to or less than twice a width of a spacer.

Specifically, the first gate insulating film pattern 60 and the first gate 70 may be formed to extend from on the drift region 40 to on the body region 50. Furthermore, the second gate insulating film pattern 65 and the second gate 75 may be formed on the drift region 40.

The gate film for forming the first gate 70 and the second gate 75 may be, but are not limited to, any one of a polysilicon film and a metal gate. When the polysilicon film is used as the gate film, it is easy to form the first and second gates 70 and 75 with a fine pitch. Therefore, a size of a semiconductor device 1 (see FIG. 1) can be reduced.

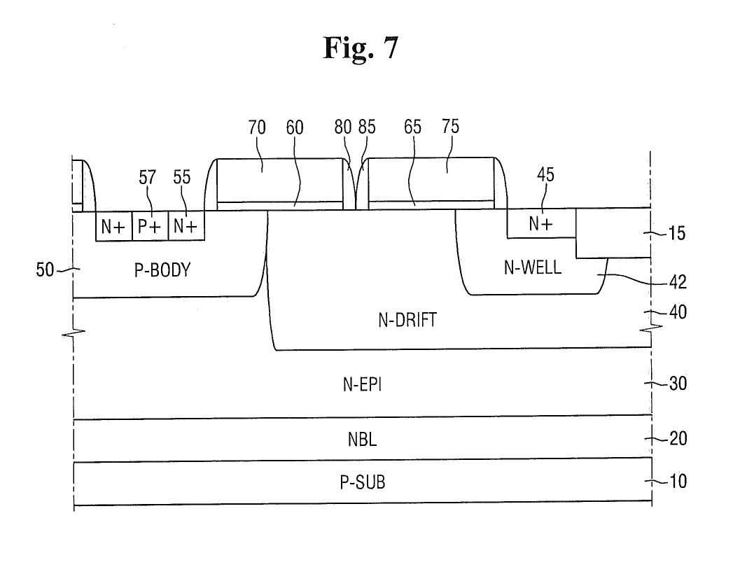

Referring to FIG. 7, a first spacer 80 may be formed on both sides of the first gate 70, and a second spacer 85 may be formed on both sides of the second gate 75. Since the gap between the first gate 70 and the second gate 75 is equal to or less than the width of a spacer, the first spacer 80 and the second spacer 85 between the first gate 70 and the second gate 75 may contact each other.

A drain region 45 of the second conductivity type, for example, an N type, may be formed on the well region 42. Furthermore, the source region 55 of the second conductivity type, for example, an N type, and an ohmic contact region 57 of the first conductivity type, for example, the P type, may be formed on the body region 50.

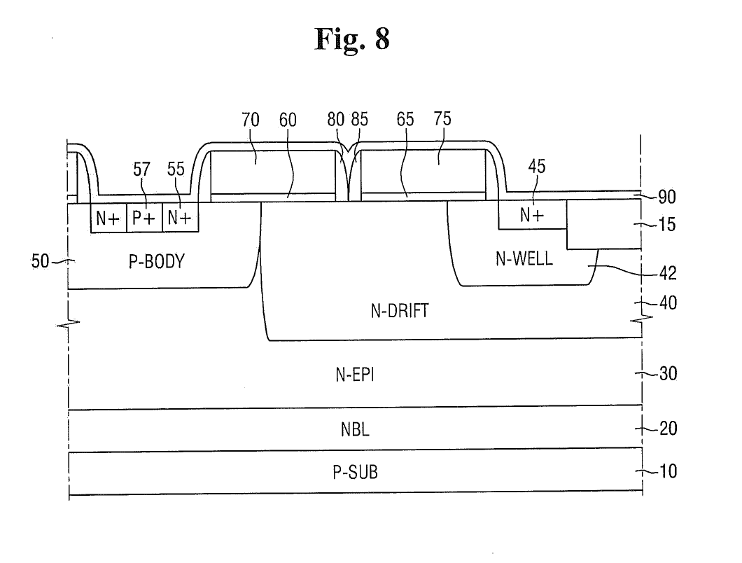

Referring to FIG. 8, a cobalt film 90 may be formed on the intermediate structure of FIG. 7. Since the second gate 75 is located between the drain region 45 and the first gate 70, a region of the drift region 40 which is located between the drain region 45 and the first gate 70 does not contact the cobalt film 90. Furthermore, since the gap between the first gate 70 and the second gate 75 is completely filled with the first and second spacers 80 and 85, a region of the drift region 40 which is located between the first gate 70 and the second gate 75 does not contact the cobalt film 90.

Referring to FIG. 1, the intermediate structure of FIG. 8 may be annealed to form a silicide. Then, a non-reacting portion of the cobalt film 90 may be removed. Specifically, a body silicide pattern 92, first and second gate silicide patterns 94 and 96, and a drain silicide pattern 98 may be formed. However, since a region of the drift region 40 which is located between the first gate 70 and the drain region 45 does not contact the cobalt film 90, no silicide may be formed.

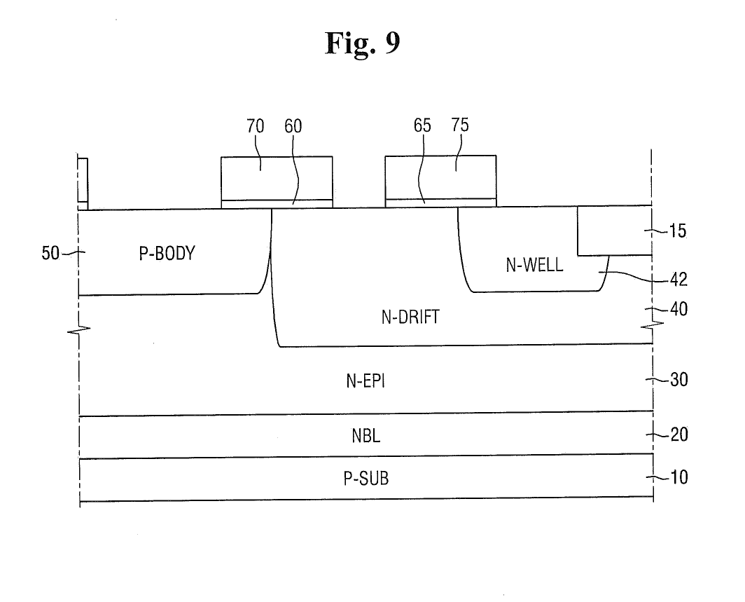

A method of fabricating a semiconductor device according to a second embodiment of the present inventive concept will now be discussed with reference to FIGS. 2, 5, and 9 through 11. For simplicity, the following description will focus on differences from the method of fabricating a semiconductor device according to the first embodiment of the present inventive concept. FIGS. 9 through 11 are cross-sections illustrating a method of fabricating a semiconductor device according to a second embodiment of the present inventive concept.

Referring to FIG. 5, a substrate 10, an element isolation region 15, a buried layer 20, an epitaxial layer 30, a drift region 40, a well region 42, and a body region 50 may be formed.

Referring to FIG. 9, a gate insulating film and a gate film may be formed sequentially on the intermediate structure of FIG. 5. Then, the gate insulating film and the gate film are patterned to form first and second gate insulating film patterns 60 and 65 and first and second gates 70 and 75.

The first gate 70 and the second gate 75 may be separated from each other. A gap between the first gate 70 and the second gate 75 may be, for example, greater than twice a width of a spacer.

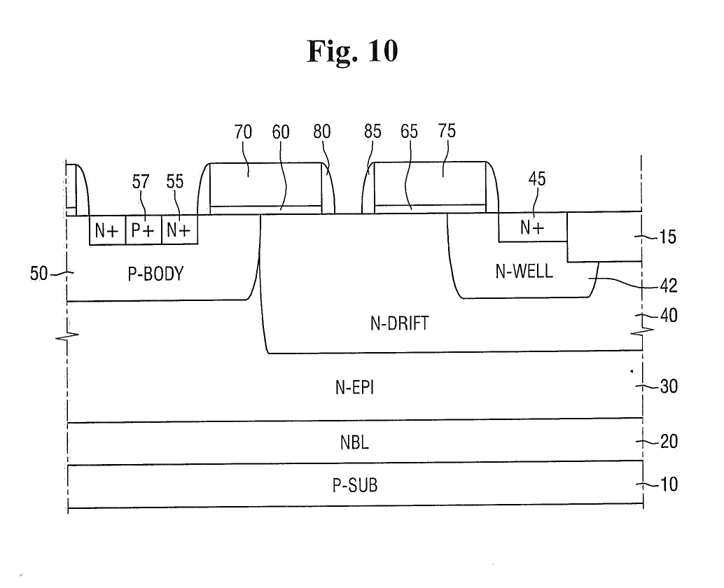

Referring to FIG. 10, a first spacer 80 may be formed on both sides of the first gate 70, and a second spacer 85 may be formed on both sides of the second spacer 75. Since the gap between the first gate 70 and the second gate 75 is greater than twice the width of the spacer, the first spacer 80 and the second spacer 85 between the first gate 70 and the second gate 75 may not contact each other but may be separated from each other.

A drain region 45 of a second conductivity type, for example, an N type, may be formed on the well region 42. Furthermore, a source region 55 of the second conductivity type, for example, an N type, and an ohmic contact region 57 of a first conductivity type, for example, the P type, may be formed on the body region 50.

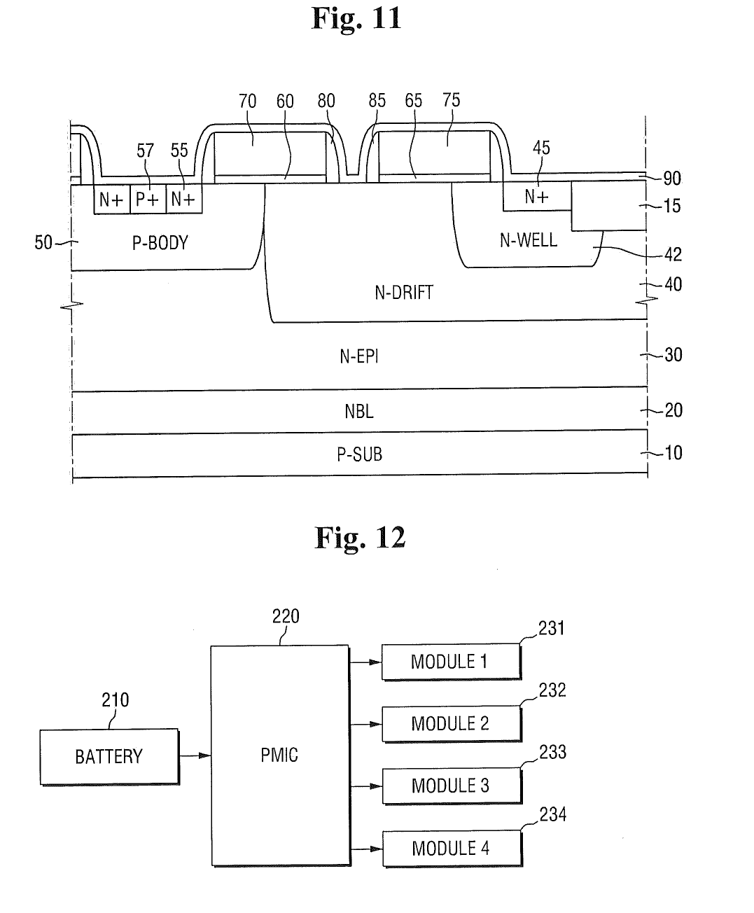

Referring to FIG. 11, a cobalt film 90 may be formed on the intermediate structure of FIG. 10. Since the first spacer 80 and the second spacer 85 between the first gate 70 and the second gate 75 are separated from each other without contacting each other, a region of the drift region 40 which is located between the first gate 70 and the second gate 75 may contact the cobalt film 90. Specifically, a region of the drift region 40 which is located between the first spacer 80 and the second spacer 85 may contact the cobalt film 90.

Referring to FIG. 2, the intermediate structure of FIG. 11 may be annealed to form a silicide. Then, a non-reacting portion of the cobalt film 90 may be removed. Specifically, a drift silicide pattern 99 may be formed on the drift region 40 between the first gate 70 and the second gate 75.

Semiconductor systems using semiconductor devices according to the above-discussed embodiments of the present inventive concept will be discussed with reference to FIGS. 12 through 15.

Referring to FIG. 12, a block diagram of a semiconductor system according to some embodiments of the present inventive concept will be discussed. As illustrated in FIG. 12, a semiconductor system according to some embodiments of the present inventive concept may include a battery 210, power management IC (PMIC) 220, and a plurality of modules 231 through 234. The PMIC 220 receives a voltage from the battery 210, shifts the received voltage to a desired voltage level for each of the modules 231 through 234, and provides the voltage at the desired voltage level to each of the modules 231 through 234. The PMIC 220 may include at least one of the semiconductor devices 1 through 4 according to the above-discussed embodiments of the present inventive concept.

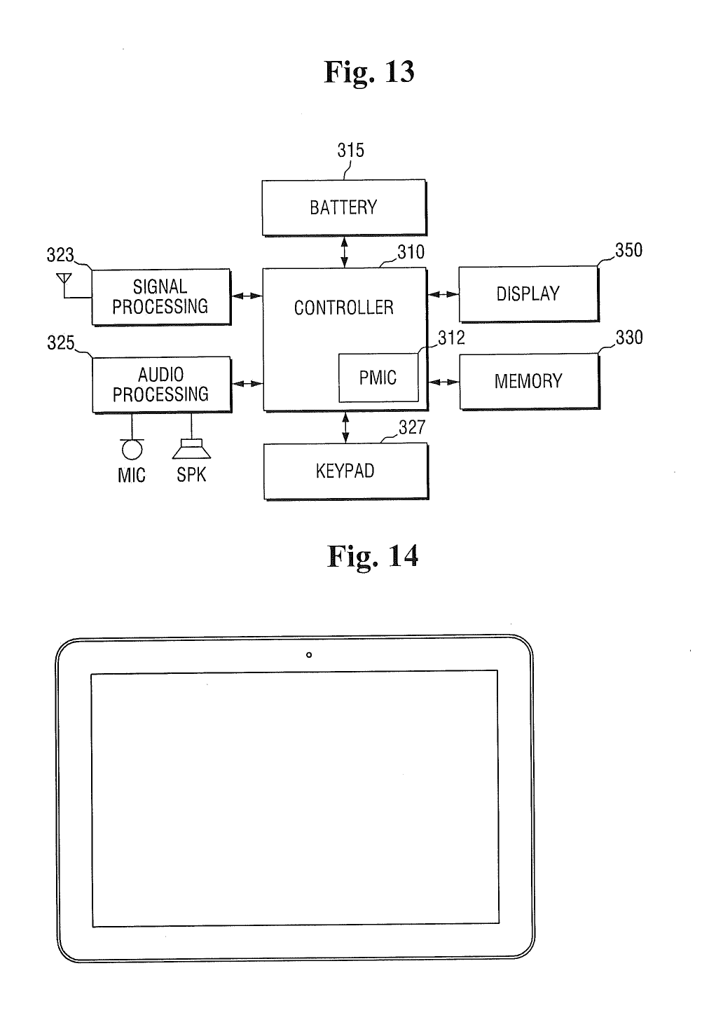

Referring now to FIG. 13, a block diagram of a semiconductor system according to some embodiments of the present inventive concept will be discussed. As illustrated in FIG. 13, the semiconductor system may be a portable terminal. The portable terminal may include a controller 310, a PMIC 312, a battery 315, a signal processing unit 323, an audio processing unit 325, a memory 330, and a display 350.

A keypad 327 includes keys for inputting numbers and text information and function keys for setting various functions. The signal processing unit 323 performs a wireless communication function of the portable terminal and includes a radio frequency (RF) unit and a modem. The RF unit includes an RF transmitter which raises and amplifies the frequency of a transmitted signal and an RF receiver which low-noise amplifies a received signal and lowers the frequency of the received signal. The modem includes a transmitter which encodes and modulates a transmitted signal and a receiver which demodulates and decodes a received signal.

The audio processing unit 325 may include codec. The codec includes data codec and audio codec. The data codec processes packet data, and the audio codec processes audio signals such as sound and multimedia files. The audio processing unit 325 converts a digital audio signal received through the modem into an analog signal using the audio codec and reproduces the analog signal or converts an analog audio signal generated by a microphone into a digital audio signal using the audio code and transmits the digital audio signal to the modem. The code may be provided as a separate element or may be included in the controller 310 of the portable terminal.

The memory 330 includes a read-only memory (ROM) and a random access memory (RAM). The memory 330 may include a program memory and a data memory. The memory 330 may store programs for controlling the operation of the portable terminal and data necessary for booting the portable terminal.

The display 350 displays an image signal and user data on the screen or displays data related to calls. The display 350 may be a liquid crystal display (LCD) or an organic light-emitting diode (OLED). When the LCD or the OLED is implemented as a touch screen, the display 350 may operate as an input unit for controlling the portable terminal, together with the keypad 327.

The controller 310 controls the overall operation of the portable terminal. The controller 310 may include the PMIC 312. The PMIC 312 receives a voltage from the battery 315 and shifts the received voltage to a desired voltage level. The PMIC 312 may include at least one of the semiconductor devices 1 through 4 according to the above-discussed embodiments of the present inventive concept.

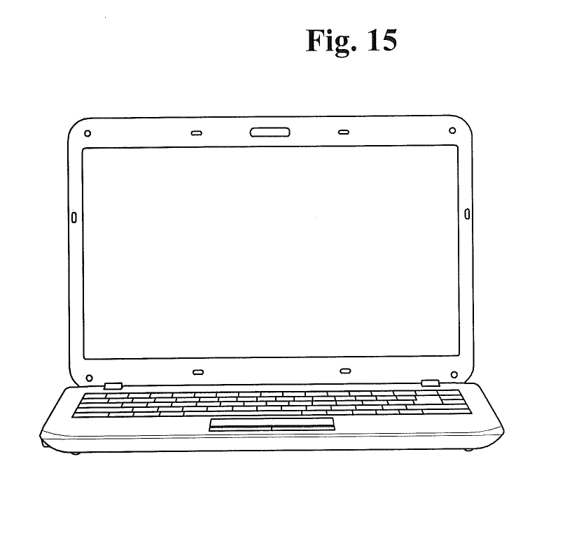

FIGS. 14 and 15 are conceptual diagrams of semiconductor systems according to third and fourth embodiments of the present inventive concept. FIG. 14 shows a tablet PC, and FIG. 15 shows a notebook computer. At least one of the semiconductor devices 1 through 4 according to the above-discussed embodiments of the present inventive concept can be used in a tablet PC, a notebook computer, and the like. It is obvious to those of ordinary skill in the art that the semiconductor devices 1 through 4 according to the above-discussed embodiments of the present inventive concept are applicable to other integrated circuit devices not exemplified herein.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A semiconductor device comprising:
a substrate having a first conductivity type;
a source region having a second conductivity type, different from the first conductivity type;
a drain region, separate from the source region and having the second conductivity type;
a body region having the first conductivity type and on the substrate surrounding side and bottom surfaces of the source region;
a drift region having the second conductivity type, the drift region being on the substrate surrounding side and bottom surfaces of the drain region;
a first gate on the body region; and
an electrically floating second gate, separate from the first gate, on the drift region.

2. The semiconductor device of claim 1, further comprising:
a first spacer on both sides of the first gate; and
a second spacer on both sides of the second gate, wherein the first spacer and the second spacer between the first gate and the second gate contact each other.

3. The semiconductor device of claim 2, wherein a region of the drift region between the first gate and the second gate is free of a silicide pattern.

4. The semiconductor device of claim 1, wherein the first gate extends from the body region and to the drift region such that at least a portion of the first gate is located on the drift region, the device further comprising a silicide pattern on a region of the drift region between the first gate and the second gate.

5. The semiconductor device of claim 4, further comprising:
a first spacer on both sides of the first gate; and
a second spacer on both sides of the second gate, wherein the first spacer and the second spacer between the first gate and the second gate are separated from each other.

6. The semiconductor device of claim 1, wherein the first and second gates are between the source region and the drain region, the first gate being adjacent to the source region and the second gate being adjacent to the drain region.

7. The semiconductor device of claim 6, further comprising:
a well region having second conductivity type in the drift region such that the well regions surround the side and bottom surfaces of the drain region;
an epitaxial layer having the second conductivity type on the substrate such that the epitaxial layer surrounds side and bottom surfaces of the body region and the drift region; and
a buried layer having the second conductivity type between the epitaxial layer and the substrate.

8. The semiconductor device of claim 7:
wherein a depth of the body region is substantially equal to a depth of the well region; and
wherein a depth of the drift region is greater than the depth of the body region.

9. The semiconductor device of claim 1, further comprising a contact plug on the first gate and electrically connected to the first gate, wherein the second gate is free of a contact plug electrically connected to the second gate.

10. The semiconductor device of claim 1, wherein the first and second gates are polysilicon gates.

11. The semiconductor device of claim 1, wherein the first conductivity type is P type and the second conductivity type is N type.

12. A semiconductor device comprising:
a substrate having a first conductivity type;
a drift region having a second conductivity type, different from the first conductivity type, on the substrate;
an electrically floating gate on the drift region;
a body region having the first conductivity type on the substrate adjacent to the drift region;
a source region which has the second conductivity type and is formed within the body region;
a gate which is located on a first side of the floating gate, which extends from on the drift region to on the body region, and to which a predetermined voltage is applied; and
a drain region which has the second conductivity type, is located on a second side of the floating gate, and is formed within the drift region.

13. The semiconductor device of claim 12, further comprising:
a first spacer on both sides of the gate; and
a second spacer on both sides of the floating gate, wherein the first spacer and the second spacer between the gate and the floating gate contact each other.

14. The semiconductor device of claim 12, further comprising:
a first spacer between the gate and the floating gate adjacent to the gate;
a second spacer between the gate and the floating gate adjacent to the floating gate; and
a silicide pattern on a region of the drift region between the first spacer and the second spacer.

15. The semiconductor device of claim 12, further comprising a contact plug on the gate that is electrically connected to the gate, wherein the floating gate is free of a contact plug electrically connected to the floating gate.
